(19) United States
(12) Patent Application Publication
(10) Pub. No.: US 2015/0062772 A1
(43) Pub. Date: Mar. 5, 2015

(54) Barrier Layer For Electrostatic Chucks

(71) Applicant: Varian Semiconductor Equipment Associates, Inc, Gloucester, MA (US)

(72) Inventors: Andrew M. Waite, Beverly, MA (US); James Carroll, Amesbury, MA (US)

(21) Appl. No.: 14/011,169

(22) Filed: Aug. 27, 2013

(51) Int. Cl. H01L 21/683

(52) U.S. Cl. CPC H01L 21/6833
USPC 361/234

(57) ABSTRACT

An electrostatic chuck for implanting ions at high temperatures is disclosed. The electrostatic chuck includes an insulating base, with electrically conductive electrodes disposed thereon. A dielectric top layer is disposed on the electrodes. A barrier layer is disposed on the dielectric top layer so as to be between the dielectric top layer and the workpiece. This barrier layer serves to inhibit the migration of particles from the dielectric top layer to the workpiece, which is clamped on the chuck. In some embodiments, a protective layer is applied on top of the barrier layer to prevent abrasion.

Embodiments of the present disclosure relate to an electrostatic chuck, and more particularly, to an electrostatic chuck having a barrier layer for use in substrate processing systems.

### BACKGROUND

Ion implanters are commonly used in the production of semiconductor workpieces. An ion source is used to create an ion beam, which is then directed toward the workpiece. As the ions strike the workpiece, they dope a particular region of the workpiece. The configuration of doped regions defines their functionality, and through the use of conductive interconnects, these workpieces can be transformed into complex circuits.

As a workpiece is being implanted, it is typically clamped to a chuck. This clamping may be mechanical or electrostatic in nature. This chuck traditionally consists of a plurality of layers. The top layer, also referred to as the dielectric layer, or dielectric top layer, contacts the workpiece, and is made of an electrically insulating or semiconducting material, such as alumina with embedded metal electrodes, since it produces the electrostatic field without creating a short circuit. Methods of creating this electrostatic field are known to those skilled in the art and will not be described herein.

A second layer, also referred to as the base, may be made from an insulating material. To create the required electrostatic force, a plurality of electrodes may be disposed between the dielectric top layer and the insulating layer. In another embodiment, the plurality of electrodes may be embedded in the insulating layer. The plurality of electrodes is constructed from an electrically conductive material, such as metal.

FIG. 1 shows a top view of a chuck 10, specifically showing the plurality of electrodes 100a-f of the chuck 10. As shown, each of the electrodes 100a-f is electrically isolated from the others. These electrodes 100a-f may be configured such that opposite electrodes have opposite voltages. For example, electrode 100a may have a positive voltage while electrode 100d may have a negative voltage. These voltages may be DC, or may vary with time to maintain the electrostatic force. For example, as shown in FIG. 1, the voltage applied to each electrode 100a-f may be a bipolar square wave. In the embodiment shown in FIG. 1, three pairs of electrodes are employed. Each pair of electrodes is in electrical communication with a respective power source 110a-c, such that one electrode receives the positive output and the other electrode receives the negative output. Each power source 110a-c generates the same square wave output, in terms of period and amplitude. However, each square wave is phase shifted from those adjacent to it. Thus, as shown in FIG. 1, electrode 100a is powered by square wave A, while electrode 100b is powered by square wave B, which has a phase shift of 120° relative to square wave A. Similarly, square wave C is phase shifted 120° from square wave B. These square waves are shown graphically on the power supplies 110a-c of FIG. 1. Of course, other numbers of electrodes and alternate geometries may be used.

The voltages applied to the electrodes 100a-f serve to create an electrostatic force, which clamps the workpiece to the chuck.

In some embodiments, it may be desirable to implant the workpiece at an elevated temperature, such as above 300° C. In these applications, impurities may migrate or diffuse from the dielectric top layer in the electrostatic chuck to the workpiece. The introduction of these impurities to the workpiece may affect yield, performance or other characteristics of the workpiece. Therefore, it may be advantageous to have a system whereby material contained within an electrostatic chuck does not diffuse or migrate to the workpiece during the hot implant process.

### SUMMARY

An electrostatic chuck for implanting ions at high temperatures is disclosed. The electrostatic chuck includes an insulating base, with electrically conductive electrodes disposed thereon. A dielectric top layer is disposed on the electrodes. A barrier layer is disposed on the dielectric top layer so as to be between the dielectric top layer and the workpiece. This barrier layer serves to inhibit the migration of particles from the dielectric top layer to the workpiece, which is clamped on the chuck. In some embodiments, a protective layer is applied on top of the barrier layer to prevent abrasion.

According to one embodiment, an electrostatic chuck is disclosed. The electrostatic chuck comprises an insulating base;

one or more electrically conductive electrodes disposed on the insulating base; a dielectric top layer, having a top surface and an opposite bottom surface, such that the electrodes are disposed between the insulating base and the dielectric top layer; and a barrier layer disposed on the top surface, wherein the barrier layer inhibits migration of particles from within the dielectric top layer to a workpiece clamped on the electrostatic chuck.

According to a second embodiment, an electrostatic chuck for use in high temperature ion implants is disclosed. The electrostatic chuck comprises an insulating base comprising a ceramic material; one or more electrically conductive electrodes disposed on the insulating base; a dielectric top layer, having a top surface and an opposite bottom surface, such that the electrodes are disposed between the insulating base and the dielectric top layer, and wherein the dielectric top layer comprises an oxide material having metal impurities introduced thereto; and a barrier layer, comprising silicon nitride, disposed on the top surface, wherein the barrier layer inhibits migration of metal particles from the dielectric top layer to a workpiece clamped on the electrostatic chuck.

### BRIEF DESCRIPTION OF THE FIGURES

For a better understanding of the present disclosure, reference is made to the accompanying drawings, which are incorporated herein by reference and in which:

FIG. 1 represents an electrostatic chuck of the prior art;

FIG. 2 shows an electrostatic chuck according to a first embodiment; and

FIG. 3 shows an electrostatic chuck according to a second embodiment.

### DETAILED DESCRIPTION

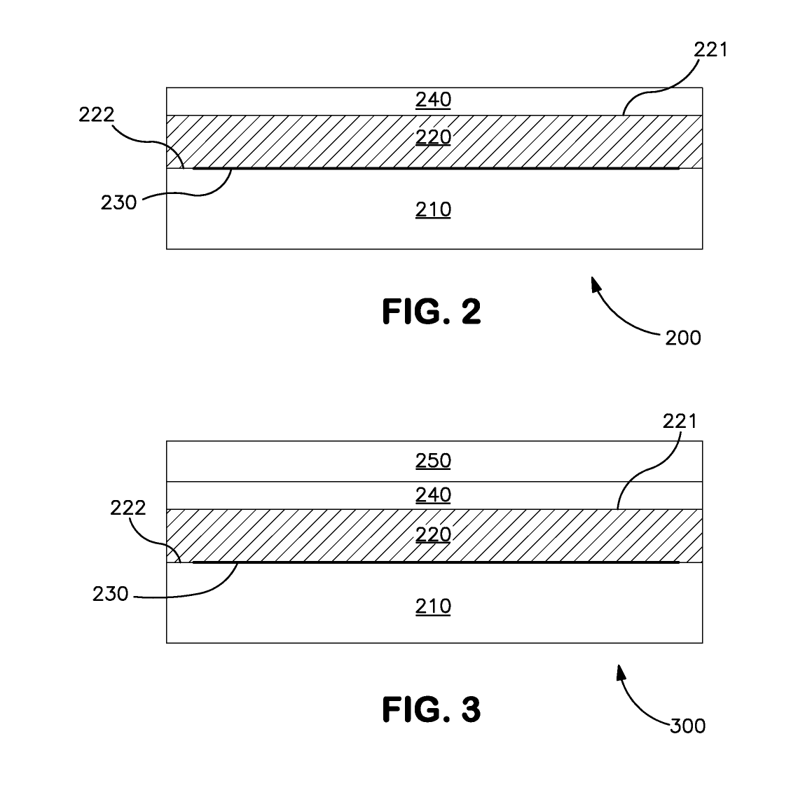

FIG. 2 shows an electrostatic chuck 200 in accordance with one embodiment. As described above, the electrostatic chuck 200 comprises an insulating base 210, and a dielectric top layer 220, with a plurality of electrodes 230 disposed between these two layers 210, 220. The workpiece (not shown) may be clamped in place by the electrostatic forces created by the chuck 200.

Furthermore, at elevated temperatures, such as above 300° C., or in some embodiments, above 500° C., it may be advantageous to heat the electrostatic chuck 200. In some embodiments, heating elements, such as heat lamps, are used to heat the workpiece disposed on the electrostatic chuck 200. Radiated heat serves to heat the electrostatic chuck 200. In other embodiments, the electrostatic chuck 200 is directly heated, either through the use of resistive elements embedded in the insulating base 210, or by passing a heated fluid through channels in the insulating base 210. In each of these embodiments, one or more heating elements are used to raise the temperature of the workpiece during the ion implant process.

Because of the amount of heat generated in the electrostatic chuck 200, it may be advantageous to utilize a heat-resistant material to create the insulating base 210. For example, ceramic materials may be capable of withstanding the heat generated in the electrostatic chuck without deformation or cracking. The insulating base 210 may be constructed of, for example, alumina or some other ceramic material. In some embodiments, a heating mechanism may be embedded in the insulating base 210. For example, the electrostatic and heating elements may be formed in the insulating base 210. Alternatively, the surface electrical properties may be modified to create a Johnsen-Rahbek type (JR type) ESC, or elements may be sandwiched between plates attached by one by one of several methods, or layers of oxides or similar materials may coat or encapsulate electrical elements.

It may be advantageous, especially at these elevated temperatures, to utilize materials for the insulating base 210 and the dielectric top layer 220 that have functionally equivalent coefficients of thermal expansion (CTE). In this disclosure, the phrase “functionally equivalent” means that the CTEs of these two layers are such that the stress generated in these two layers due to thermal expansion can be tolerated without causing either layer to fracture. Furthermore, this phrase means that the CTEs are such that adhesion between these layers does not fail, causing the layers to separate. In some embodiments, these CTEs may be, for example, within 15% of each other over the intended temperature range. However, a larger or smaller percentage difference may be required to insure the above conditions are met. In another embodiment, these CTEs may be within 20% of each other over the intended temperature range.

At these elevated temperatures, it may be beneficial to create the dielectric top layer 220 from some type of oxide, such as silicon oxide, or other high temperature tolerant material, such as a ceramic material. To modify the CTE of the material used for the dielectric top layer 220, impurities may be added to that material. For example, particles, such as magnesium, lead or zinc, may be added to the oxide or ceramic material to create a CTE that is functionally equivalent to that of the insulating base 210. Thus, the dielectric top layer 220 may be an oxide material with impurities intentionally introduced to alter its thermal or dielectric properties. Alternatively, the dielectric top layer 220 may be a ceramic material with impurities intentionally introduced to alter its thermal or dielectric properties.

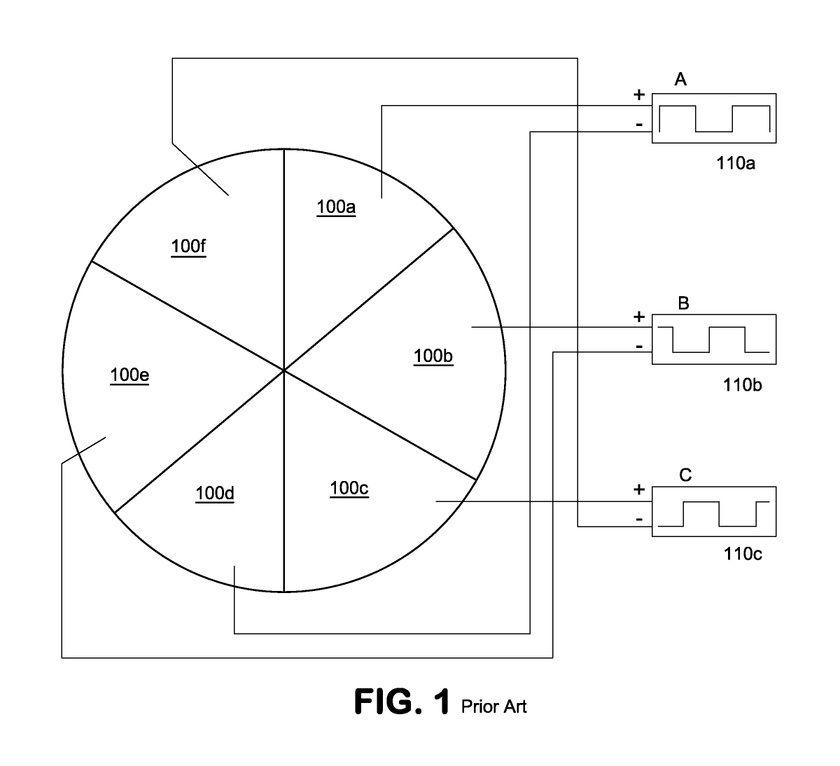

As described above, electrically conductive electrodes 230 are disposed on the insulating base 210 prior to the introduction of the dielectric top layer 220. These electrodes 230 may be created by deposition of a metal on the insulating base 210, or using other techniques known in the art. In some embodiments, these electrodes 230 are constructed of a conductive metal. The electrodes 230, or the material coating the electrodes 230, may contain trace materials, such as copper, for example, that may migrate to the top surface 221. As described in FIG. 1, each electrode 230 is in electrical communication with a power source (not shown), as described above.

After deposition of the electrodes 230, the dielectric top layer 220 is applied. For example, the dielectric top layer 220 may be applied using silk screening, spin coating or using a vapor deposition process. The dielectric top layer 220 has a bottom surface 222 which is in contact with the electrodes 230 and an opposite top surface 221. It has been discovered that, unexpectedly, at elevated temperatures, material contained within the dielectric top layer 220, such as the metal particles, diffuses or migrates toward the top surface 221 of the dielectric top layer 220. At these elevated temperatures, after reaching the top surface 221, unless otherwise prevented from doing so, these materials may diffuse or migrate into the surface of the workpiece proximate the top surface 221. Thus, when the workpiece is removed by the electrostatic chuck 200, these materials become attached or embedded in the workpiece, thereby impacting the performance or utility of the workpiece.

These effects do not appear to occur at lower temperatures, such as room temperature, and thus have never been previously addressed.

Specifically, testing has shown that particles of zinc, magnesium, lead and copper are considered to be those most likely to diffuse or migrate from the dielectric top layer 220 into the workpiece. These particles may be the impurities added to the oxide or ceramic material used to create the dielectric top layer 220, which were introduced to create the desired thermal and dielectric properties. Therefore, the removal of these particles from the dielectric top layer 220 may not be advisable or even possible. In other embodiments, these particles may come in contact with the electrostatic chuck 200 during the manufacturing process. Changes to the manufacturing process to eliminate contact with these particles may be impractical. In addition, these particles may have been used in the fabrication of the electrodes 230. For example, copper, used in the fabrication of the electrodes 230, may comprise one of these particles. Thus, these particles may not be easily removed from the dielectric top layer 220. Therefore, it may be necessary to devise a system and method by which these particles, which are known to migrate toward the surface 221, are kept away from the workpiece.

In a first embodiment, a barrier layer 240 is applied to the top surface 221 of the dielectric top layer 220. This barrier layer 240 serves to stop the migration of particles from the dielectric top layer 220 to the workpiece that is clamped on the chuck 200. Thus, the composition of the barrier layer 240 may be a material that inhibits the migration of these particles. In other embodiments, the composition of the barrier layer 240 may be such that it impedes the migration of these metal particles. In some embodiments, a nitride, such as silicon nitride, may be used.

This barrier layer 240 may be applied to a thickness of, for example, less than 10 microns. This thickness may be selected based on the time required to apply the barrier layer 240 and its effect of the electrostatic forces. This thickness may have minimal effect on the electrostatic forces created by the chuck 200. Similarly, at this thickness, the CTE of the barrier layer 240 may be of little importance. This barrier layer 240 may be applied to the top surface 221 of the dielectric top layer 220 using, for example, chemical vapor deposition (CVD), although other deposition processes may also be employed. Optionally, the barrier layer 240 may also be applied to the sides of the dielectric top layer 220.

Additionally, nitrides, such as silicon nitride, are very hard materials, and therefore may be resistant to mechanical abrasion between the chuck 200 and the workpiece being implanted on the chuck 200.

Thus, particles from within the dielectric top layer 220 may still migrate to the top surface 221 of the dielectric top layer 220. However, their further migration is inhibited by the presence of barrier layer 240. Thus, the workpiece clamped on the barrier layer 240 is protected from these potentially harmful particles.

FIG. 3 shows an electrostatic chuck 300, according to a second embodiment. This embodiment is similar to that of FIG. 2 and similar components are given consistent reference designators, and will not be described again. As before, the barrier layer 240 may be a nitride, such as silicon nitride. The thickness of this barrier layer 240 may be, for example, less than 1 micron thick. In some embodiments, it may be hundreds of nanometers in thickness. In this embodiment, an additional protective layer 250 is applied on top of the barrier layer 240. This protective layer 250 may be, for example, hundreds of microns in thickness. In other embodiments, the protective layer 250 may be as thick as 1 mm. The protective layer 250 is intended to protect the electrostatic chuck 300, and particularly the barrier layer 240 from abrasion, which may result from contact with the workpieces. In one embodiment, the protective layer 250 is comprised of borosilicate glass (BSG). Other suitable materials may be used which are insulating, and do not affect the electrostatic fields being created.

Thus, a high temperature ion implant may be performed by clamping a workpiece on an electrostatic chuck 200 having the barrier layer 240 described herein. The barrier layer 240 serves to inhibit the migration of metal particles from the dielectric top layer 220 to the workpiece, thereby maintaining the integrity of the workpiece. As described above, these particles may be impurities added to the dielectric top layer 220 to alter its thermal or dielectric properties. These particles may be materials used in the fabrication of the electrodes 230. To perform the high temperature ion implant, heating elements may be used to raise the temperature of the workpiece to about 300° C. during the ion implant process.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An electrostatic chuck, comprising:
an insulating base;
one or more electrically conductive electrodes disposed on said insulating base;
a dielectric top layer, having a top surface and an opposite bottom surface, such that said electrodes are disposed between said insulating base and said dielectric top layer; and
a barrier layer disposed on said top surface, wherein said barrier layer inhibits migration of particles from within said dielectric top layer to a workpiece clamped on said electrostatic chuck.

2. The electrostatic chuck of claim 1, wherein said barrier layer comprises silicon nitride.

3. The electrostatic chuck of claim 1, wherein said dielectric top layer comprises an oxide or ceramic material with metal impurities introduced so as to alter its thermal or dielectric properties, and said migrated particles comprise said metal impurities.

4. The electrostatic chuck of claim 3, wherein said migrated particles are selected from the group consisting of magnesium, lead, and zinc.

5. The electrostatic chuck of claim 1, wherein said migrated particles are used in fabrication of said electrodes.

6. The electrostatic chuck of claim 5, wherein said migrated particles comprise copper particles.

7. The electrostatic chuck of claim 1, further comprising a protective layer disposed on said barrier layer.

8. The electrostatic chuck of claim 7, wherein said protective layer comprises borosilicate glass having a thickness of less than 1 mm.

9. An electrostatic chuck for use in high temperature ion implants, comprising:
an insulating base comprising a ceramic material;
one or more electrically conductive electrodes disposed on said insulating base;
a dielectric top layer, having a top surface and an opposite bottom surface, such that said electrodes are disposed between said insulating base and said dielectric top layer, and wherein said dielectric top layer comprises an oxide material having metal impurities introduced thereto; and
a barrier layer, comprising silicon nitride, disposed on said top surface, wherein said barrier layer inhibits migration of metal particles from said dielectric top layer to a workpiece clamped on said electrostatic chuck.

10. The electrostatic chuck of claim 9, wherein said metal particles comprise said metal impurities introduced to said oxide material.

11. The electrostatic chuck of claim 10, wherein said metal impurities are introduced so as to alter a thermal or dielectric property of said oxide material.

12. The electrostatic chuck of claim 9, wherein said metal particles are used in fabrication of said electrodes.

13. The electrostatic chuck of claim 9, wherein said metal particles are selected from the group consisting of magnesium, lead, copper, and zinc.

14. The electrostatic chuck of claim 9, further comprising a protective layer disposed on said barrier layer.

15. The electrostatic chuck of claim 14, wherein said protective layer comprises borosilicate glass having a thickness of less than 1 mm.
